(19) United States
(12) Patent Application Publication
(10) Pub. No.: US 2025/0265377 A1
(43) Pub. Date: Aug. 21, 2025

(54) WORK SIMULATION SYSTEM, WORK SIMULATION METHOD, AND RECORDING MEDIUM

(71) Applicant: Panasonic Intellectual Property Management Co., Ltd., Osaka (JP)

(72) Inventors: Kotaro SAKATA, Osaka (JP); Tetsuji Fuchikami, Osaka (JP)

(21) Appl. No.: 19/202,494

(22) Filed: May 8, 2025

Related U.S. Application Data
(63) Continuation of application No. PCT/JP2023/036684, filed on Oct. 10, 2023.

(30) Foreign Application Priority Data
Nov. 24, 2022 (JP) 2022-187308

(51) Int. Cl. G06F 30/13

(52) U.S. Cl. CPC G06F 30/13

(57) ABSTRACT

A work simulation system that performs a work simulation simulating work on a work site in a virtual space, and includes: an information obtainer that obtains work achievement information of a work trainee who participates in the work simulation; a proficiency level setter that sets the proficiency level of other worker in the vicinity of the work trainee on the work site based on the work achievement information; and a behavior generator that generates a behavior of the other worker on the work site in accordance with the proficiency level of the other worker.

### CROSS REFERENCE TO RELATED APPLICATIONS

This is a continuation application of PCT International Application No. PCT/JP2023/036684 filed on Oct. 10, 2023, designating the United States of America, which is based on and claims priority of Japanese Patent Application No. 2022-187308 filed on Nov. 24, 2022. The entire disclosures of the above-identified applications, including the specifications, drawings and claims are incorporated herein by reference in their entirety.

### FIELD

The present disclosure relates to a work simulation system, a work simulating method, and a recording medium.

### BACKGROUND

Patent Literature (PTL) 1 discloses a system that presents to a trainee training content based on three-dimensional shape information and work procedure of a target device with which the trainee works, and causes the trainee to participate in the simulation of work on a work site in accordance with the work procedure in the simulation work space of virtual reality. In this system, a simulated accident is generated at a training level to give the trainee a strong impression of the risk of an accident.

### CITATION LIST

### Patent Literature

PTL 1: Japanese Unexamined Patent Application Publication No. 2020-4218

### SUMMARY

### Technical Problem

For example, a worker on a work site may be affected due to the behavior of other worker in the vicinity of the worker and may be exposed to a danger in other work in some cases. Therefore, conducting work training in which the behavior of other worker is reflected is demanded.

In view of this, the present disclosure provides, for instance, a work simulation system capable of conducting work training in which the behavior of other worker is reflected.

### Solution to Problem

A work simulation system according to one aspect of the present disclosure is a work simulation system that performs a work simulation simulating work on a work site in a virtual space, and includes: an information obtainer that obtains work achievement information of a work trainee who participates in the work simulation; a proficiency level setter that sets the proficiency level of other worker in the vicinity of the work trainee on the work site based on the work achievement information; and a behavior generator that generates a behavior of the other worker on the work site in accordance with the proficiency level of the other worker.

A work simulation system according to one aspect of the present disclosure is a work simulation system that performs a work simulation simulating work on a work site in a virtual space, and includes: an information obtainer that obtains work achievement information of a work trainee who participates in the work simulation; and a behavior generator that generates a behavior of other worker in the vicinity of the work trainee on the work site based on the work achievement information.

A work simulation method according to one aspect of the present disclosure is a work simulation method of performing a work simulation simulating work on a work site in a virtual space, and includes: obtaining work achievement information of a work trainee who participates in the work simulation; setting a proficiency level of other worker in the vicinity of the work trainee on the work site based on the work achievement information; and generating a behavior of the other worker on the work site in accordance with the proficiency level of the other worker.

A recording medium according to one aspect of the present disclosure is a non-transitory computer-readable recording medium for use in a computer, where the recording medium has recorded thereon a computer program for causing the computer to execute the aforementioned work simulation method.

### Advantageous Effects

With the work simulation system and so on according to one aspect of the present disclosure, it is possible to conduct work training in which the behavior of other worker is reflected.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a schematic diagram illustrating a work simulation system according to an embodiment.

FIG. 2 is a diagram illustrating the block configuration of the work simulation system.

FIG. 3 is a diagram illustrating one example of a work site in a virtual space.

FIG. 4 is a diagram illustrating one example of a user interface device included in the work simulation system.

FIG. 5 is a diagram illustrating one example of work achievement information of a worker.

FIG. 6 is a diagram illustrating a list of work details on a work site.

FIG. 7 is a diagram illustrating examples of an unsafe behavior on a work site.

FIG. 8 is a flowchart illustrating a work simulation method according to the embodiment.

FIG. 9 is a diagram illustrating the configuration of a work simulation system according to Variation 1 of the embodiment.

FIG. 10 is a diagram illustrating the configuration of a work simulation system according to Variation 2 of the embodiment.

FIG. 11 is a diagram illustrating another example of the user interface device.

### DESCRIPTION OF EMBODIMENT

Workers having various proficiency levels come and go in the same space on a work site such as a construction site. In a conventional system that conducts work training in a virtual space, however, the proficiency levels of other workers in the vicinity of a worker are not considered. For this reason, satisfactory work training that considers the proficiency levels of other workers could not be conducted in a work simulation in a virtual space.

In view of this, a work simulation system according to Example 1 is a work simulation system that performs a work simulation simulating work on a work site in a virtual space, and includes: an information obtainer that obtains work achievement information of a work trainee who participates in the work simulation; a proficiency level setter that sets a proficiency level of other worker in the vicinity of the work trainee on the work site based on the work achievement information; and a behavior generator that generates a behavior of the other worker on the work site in accordance with the proficiency level of the other worker.

By thus generating a behavior of other worker in accordance with the proficiency level of the other worker, it is possible to conduct work training in which the behavior of the other worker is reflected.

A work simulation system according to Example 2 may be the work simulation system according to Example 1, and the behavior generator may generate an unsafe behavior on the work site and causes the other worker to perform the unsafe behavior.

By thus causing other worker to perform an unsafe behavior, it is possible to conduct work training in which the unsafe behavior of the other worker is reflected.

A work simulation system according to Example 3 may be the work simulation system according to Example 1 and Example 2, and the behavior generator may generate a behavior in work with high accident probability and cause the other worker to perform the behavior.

With the above feature, it is possible to cause other worker to perform a behavior in work with high accident probability. This makes it possible to conduct work training in which a behavior of other worker in work with high accident probability is reflected.

A work simulation system according to Example 4 may be the work simulation system according to any one of Example 1 to Example 3, and the proficiency level setter may set, as the proficiency level of the other worker, a proficiency level different from the proficiency level of the work trainee.

With the above feature, it is possible to conduct work training in which a behavior of other worker having a proficiency level different from the proficiency level of a work trainee is reflected.

A work simulation system according to Example 5 may be the work simulation system according to any one of Example 1 to Example 3, and the proficiency level setter may set, as the proficiency level of the other worker, a proficiency level different from the proficiency level of other worker with whom the work trainee has worked in collaboration in the past.

With the above feature, it is possible to conduct work training in which a behavior of other worker having a proficiency level different from the proficiency level of a work trainee in the past is reflected.

A work simulation system according to Example 6 may be the work simulation system according to any one of Example 1 to Example 3, and the proficiency level setter may select, as the proficiency level of the other worker, the setting level of a proficiency level with less collaborative work experience for the work trainee from among setting levels of stepped proficiency levels.

With the above feature, it is possible to conduct work training in which a behavior of other worker having the setting level of a proficiency level with less collaborative work experience is reflected.

A work simulation system according to Example 7 may be the work simulation system according to Example 2 or Example 3, and may further include: an unsafe behavior extractor that extracts an unsafe behavior of the work trainee in the past based on the work achievement information. The behavior generator may generate an unsafe behavior on the work site based on the unsafe behavior in the past extracted by the unsafe behavior extractor.

With the above feature, it is possible to cause other worker to perform an unsafe behavior of the work trainee in the past. This makes it possible to conduct work training in which an unsafe behavior of a work trainee in the past is reflected.

A work simulation system according to Example 8 may be the work simulation system according to Example 2 or Example 3, and may further include: an unsafe behavior extractor that extracts an unsafe behavior of the work trainee in the past based on the work achievement information; and a dangerous work setter that sets dangerous work with high accident probability based on the unsafe behavior in the past. The behavior generator may generate a behavior of the other worker based on the dangerous work with high accident probability set by the dangerous work setter.

With the above feature, it is possible to cause other worker to perform a behavior based on dangerous work with high accident probability. This makes it possible to conduct work training in which a behavior based on dangerous work with high accident probability is reflected.

A work simulation system according to Example 9 may be the work simulation system according to Example 2 or Example 3, and may further include: an unsafe behavior extractor that extracts an unsafe behavior of the work trainee in the past based on the work achievement information; a dangerous work setter that sets dangerous work with high accident probability based on the unsafe behavior in the past; and a user interface device that presents the dangerous work with high accident probability.

By thus presenting dangerous work with high accident probability, it is possible to conduct work training in which a behavior based on the dangerous work with high accident probability is reflected.

A work simulation system according to Example 10 is a work simulation system that performs a work simulation simulating work on a work site in a virtual space, and includes: an information obtainer that obtains work achievement information of a work trainee who participates in the work simulation; and a behavior generator that generates a behavior of other worker in the vicinity of the work trainee on the work site based on the work achievement information.

By thus generating a behavior of other worker based on work achievement information, it is possible to conduct work training in which the behavior of the other worker is reflected.

A work simulation method according to Example 11 is a work simulation method of performing a work simulation simulating work on a work site in a virtual space, and may include: obtaining work achievement information of a work trainee who participates in the work simulation; setting a proficiency level of other worker in the vicinity of the work trainee on the work site based on the work achievement information; and generating a behavior of the other worker on the work site in accordance with the proficiency level of the other worker.

By thus generating a behavior of other worker in accordance with the proficiency level of the other worker, it is possible to conduct work training in which the behavior of the other worker is reflected.

A recording medium according to Example 12 is a non-transitory computer-readable recording medium for use in a computer, the recording medium having recorded thereon a computer program for causing the computer to execute the work simulation method according to Example 11.

With this, it is possible to cause a computer to execute the aforementioned work simulation method using a non-transitory computer-readable recording medium having recorded thereon the aforementioned program.

These general or specific aspects of the present disclosure may be implemented using a system, a device, a method, an integrated circuit, a computer program, or a computer-readable non-transitory recording medium such as a CD-ROM, or any combination of systems, devices, methods, integrated circuits, computer programs, and recording media.

Hereinafter, an embodiment of the present disclosure will be described with reference to the drawings. The embodiment described below illustrates a general or specific example of the present disclosure. The numerical values, shapes, materials, elements, the arrangement and connection of the elements, steps, and orders of steps etc., shown in the following embodiment are mere examples, and therefore are not intended to limit the scope of claims of the present disclosure.

### EMBODIMENT

### Configuration of Work Simulation System

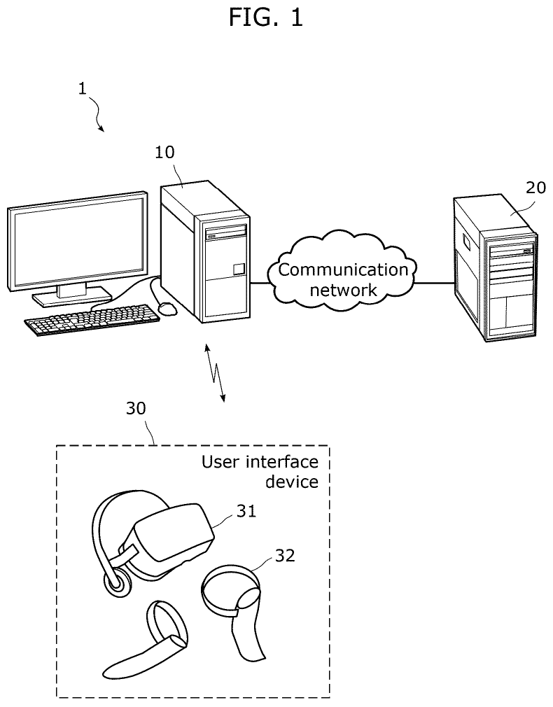

The configuration of a work simulation system according to an embodiment will be described with reference to FIG. 1 to FIG. 7.

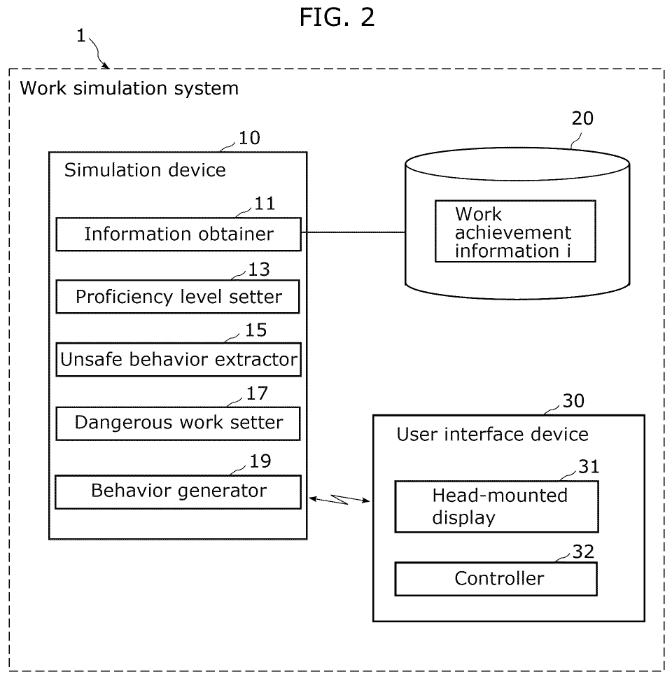

FIG. 1 is a schematic diagram illustrating work simulation system 1 according to the embodiment. FIG. 2 is a diagram illustrating the block configuration of work simulation system 1.

Work simulation system 1 illustrated in FIG. 1 and FIG. 2 includes simulation device 10, database server 20, and user interface device 30. Hereinafter, user interface device 30 may be referred to as UI device 30.

Simulation device 10 and database server 20 are connected by wires or wirelessly for communication. Simulation device 10 and database server 20 may be connected to each other via a communication network. Simulation device 10 and UI device 30 are connected wirelessly by, for instance, WiFi (registered trademark) or Bluetooth (registered trademark) for communication.

Work simulation system 1 is a system that performs a work simulation simulating work on a work site in virtual space (imaginary space) S.

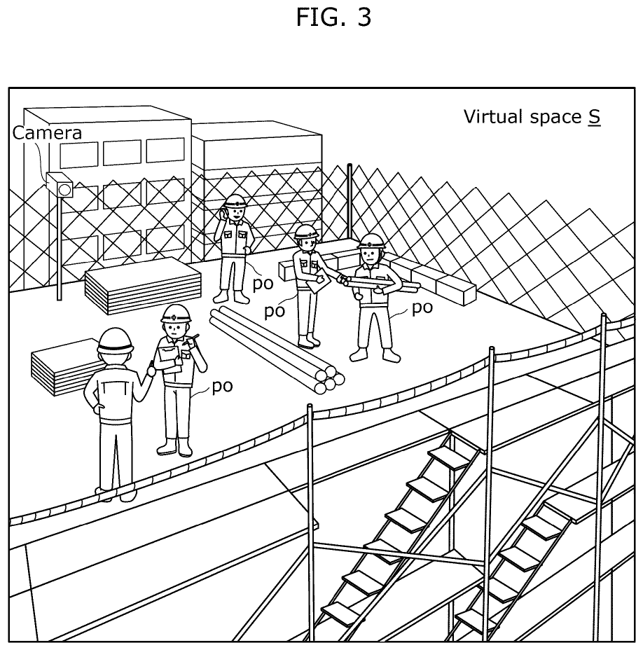

FIG. 3 is a diagram illustrating one example of a work site in virtual space S.

The figure illustrates a construction site that is one example of a work site. The work site illustrated in the figure is a space that is virtually created. Note that the work site is not limited to a construction site and may be a site at a repair shop in which vehicles are repaired or a site in a production factory where products are manufactured.

FIG. 3 illustrates how a plurality of workers work on the work site of a building that is under construction. A work trainee receives safe training by experiencing a dangerous behavior on purpose on a work site in virtual space S. By experiencing a dangerous behavior in virtual space S, a danger can be predicted or avoided on an actual work site.

Work simulation system 1 according to the present embodiment is configured to provide an opportunity to experience a dangerous behavior using UI device 30 described below.

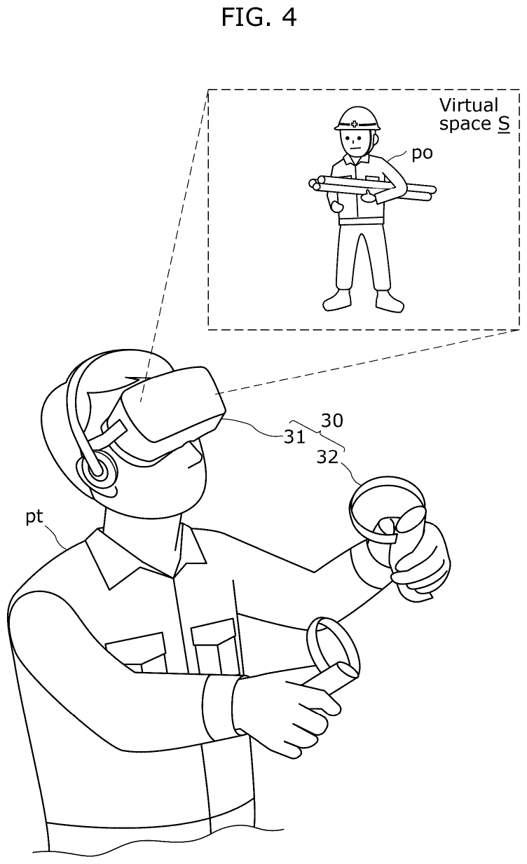

FIG. 4 is a diagram illustrating one example of user interface device 30 included in work simulation system 1.

UI device 30 includes, for example, head-mounted display 31 and controller 32. Note that UI device 30 may be a smartphone, a tablet terminal, smart glasses, or a terminal device like a gaming device. Hereinafter, head-mounted display 31 may be referred to as HMD 31.

HMD 31 is attached to the head of work trainee pt and provides work trainee pt with a video and sound. For example, HMD 31 generates, for instance, a video showing a work site based on information transmitted from simulation device 10. Controller 32 is held by the hands of work trainee pt and transmits an operation input by work trainee pt to HMD 31. HMD 31 reflects the movement of work trainee pt in the video based on the operation input transmitted from controller 32.

Virtual space S in FIG. 4 shows how other worker po who works in collaboration with work trainee pt carries construction materials. In this example, work trainee pt himself is shown in virtual space S and the avatar of work trainee pt is not shown.

When other worker po collides with work trainee pt or work trainee pt himself falls down, UI device 30 gives vibration or acceleration to controller 32 so that work trainee pt feels that the collision or fall has occurred. The behavior of other worker po in virtual space S is generated based on, for instance, information stored in database server 20 described below.

Database server 20 is, for example, a computer device, and input and output, editing, and saving of various information are performed. Database server 20 stores work achievement information i of each of workers. Database server 20 includes an external storage device such as a network attached storage (NAS).

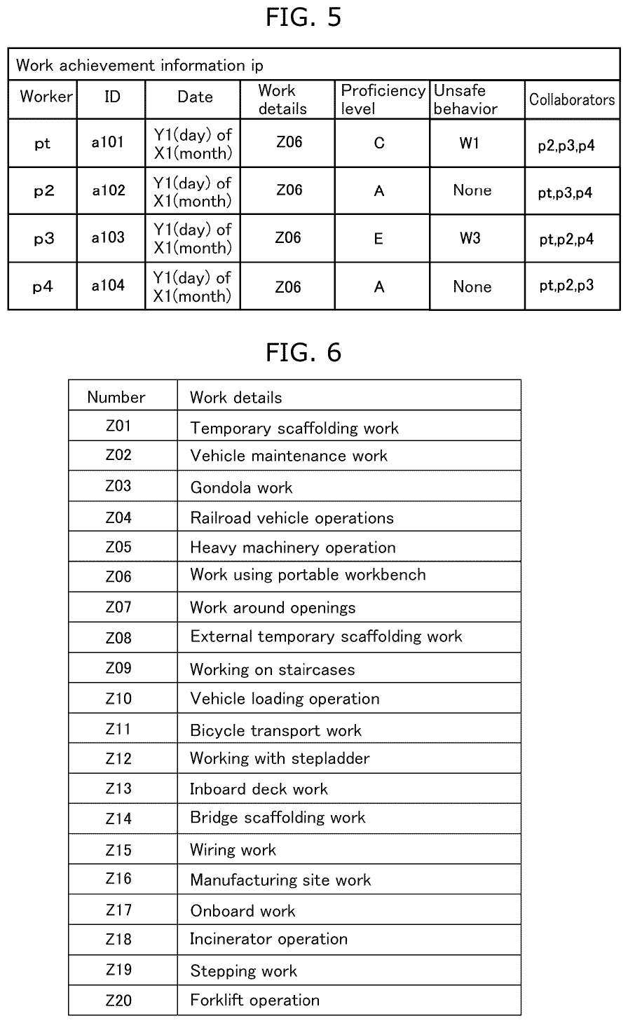

FIG. 5 is a diagram illustrating one example of work achievement information i of a worker.

Database server 20 stores work achievement information i of work trainee pt who is going to receive work training, as well as work achievement information i of other workers p2, p3, and p4 different from work trainee pt.

Work achievement information i includes identification information of a worker and information regarding a work history. The identification information of a worker is a worker ID such as an employee's number. The information regarding a work history includes a working day, work details, and information regarding unsafe behaviors. FIG. 5 shows that the worker ID of work trainee pt is a101, work details on Y1 (day) of X1 (month) is work Z06, and unsafe behavior W1 of work trainee pt occurred in work Z06. Work achievement information i includes also information on other workers p2, p3, and p4 with whom a worker has worked in collaboration in the past. The information on other workers p2, p3, and p4 is referenced when the proficiency level of other worker po is set in a simulation.

FIG. 6 is a diagram illustrating a list of work details on a work site.

A list of work details illustrated in FIG. 6 is stored in database server 20 in advance. The figure illustrates “work using a portable workbench” as one example of work details. The work details are leveled into, for instance, large classifications, medium classifications, and small classifications, and stored. For example, subdivided work details such as “climb up on a workbench, stand on a workbench, and use a tool” may be stored together with the work details “work using a portable workbench”. The list of these work details is stored in database server 20 by, for example, downloading information disclosed on the Internet.

The work details of a worker in the past that are stored as information regarding a work history are stored from an attendance management system for workers into database server 20. The work details in the past may be input to database server 20 using the input terminal of a computer device or may be input to database 20 based on video information of a camera provided on an actual (real) work site.

Database server 20 stores unsafe behaviors that may occur in each of the work details.

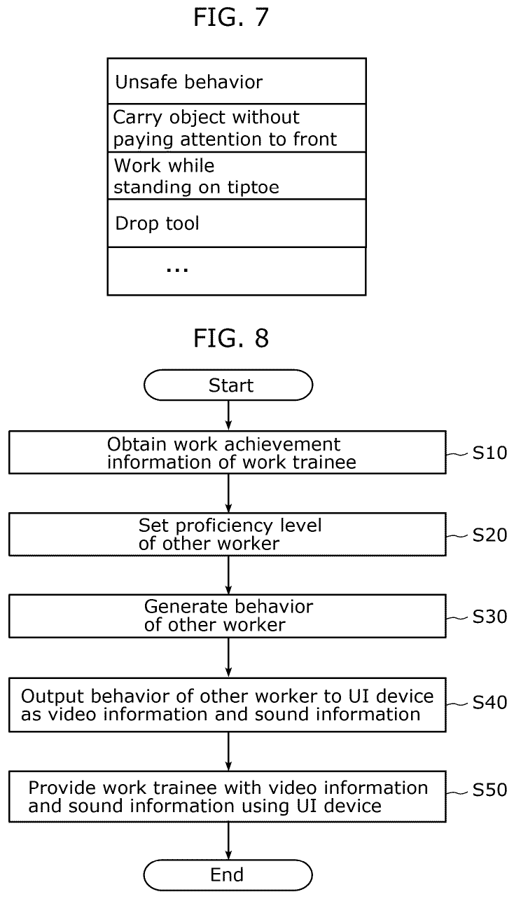

FIG. 7 is a diagram illustrating examples of an unsafe behavior on a work site.

Unsafe behaviors include dangerous behaviors and behaviors that lead to accidents. The figure shows “carry an object without paying attention to front, work while standing on tiptoe, and drop a tool” as examples of unsafe behaviors. These unsafe behaviors are, for example, stored in database server 20 by downloading information disclosed on the Internet.

Unsafe behaviors of a worker in the past are stored in database server 20 as information regarding a work history.

Whether a behavior of a worker in the past is an unsafe behavior is determined through, for example, artificial intelligence (AI) analysis of analyzing video information of a worker on an actual work site. Database server 20 obtains video information of a worker from a camera provided on an actual work site, flags a video showing an unsafe behavior of the worker, and records the unsafe behavior as history information of the worker. An unsafe behavior may be detected by an acceleration sensor attached to the helmet of a worker. An unsafe behavior may be stored in database server 20 using the input terminal of a computer device.

Work achievement information i illustrated in FIG. 5 includes information regarding the proficiency level of a worker. Proficiency levels, which are divided into, for example, levels from proficiency level A that is a high proficiency level to proficiency level E that is a low proficiency level, are input. The figure illustrates that the proficiency level of work trainee pt for work Z06 is C. The proficiency level of a worker is determined for each of work details of the worker by evaluating, for instance, years of experience of the worker, experience frequency, work quality, and presence or absence of an unsafe behavior. The proficiency levels may be input through AI analysis or by a supervisor on a work site.

Simulation device 10 generates a behavior of other worker po in the vicinity of work trainee pt who participates in a work simulation, based on such work achievement information i. Hereinafter, each of elements included in simulation device 10 will be described.

As illustrated in FIG. 2, simulation device 10 includes information obtainer 11, proficiency level setter 13, and behavior generator 19. Simulation device 10 includes also unsafe behavior extractor 15 and dangerous work setter 17.

Information obtainer 11 is a processing circuit that obtains work achievement information i of a worker. Information obtainer 11 obtains work achievement information i of each of workers from database server 20. Work achievement information i includes identification information of a worker, information regarding a work history, and information regarding the proficiency level of the worker. When work achievement information i does not include information regarding a proficiency level, information obtainer 11 may evaluate the work details of a worker based on the work history of the worker to obtain the proficiency level of the worker.

Information obtainer 11 according to the present embodiment obtains at least work achievement information i of work trainee pt who participates in a work simulation. Work achievement information i obtained by information obtainer 11 is output to proficiency level setter 13.

Proficiency level setter 13 is a processing circuit that sets the proficiency level of other worker po in the vicinity of work trainee pt on a work site based on work achievement information i. The reason for setting the proficiency level of other worker po in performing a simulation is because the behavior of other worker po in the vicinity of work trainee pt is different depending on the proficiency level of other worker po. Proficiency level setting methods include a plurality of setting methods indicated below.

The first proficiency level setting method will be described. Proficiency level setter 13 sets, as the proficiency level of other worker po, a proficiency level different from the proficiency level of work trainee pt. When the proficiency level of work trainee pt is C (see FIG. 5), for example, proficiency level setter 13 sets the proficiency level of other worker po to A, B, D, or E. When a plurality of other workers po are present, proficiency level setter 13 may assign proficiency level A, B, D, and E to the plurality of other workers po. Thus, work trainee pt works with other worker po having a proficiency level different from his/her own proficiency level, and experiences a danger caused by a behavior of that other worker po.

The second proficiency level setting method will be described. Proficiency level setter 13 sets, as the proficiency level of other worker po, a proficiency level different from the proficiency levels of other workers p2, p3, and p4 with whom work trainee pt has worked in collaboration in the past. When the proficiency levels of other workers p2, p3, and p4 are A, E, and A (see FIG. 5), for example, proficiency level setter 13 sets the proficiency level of other worker po to B, C, or D. When a plurality of workers po are present, proficiency level setter 13 may assign proficiency levels B, C, and D to the plurality of workers po. Thus, work trainee pt works with other worker po having a proficiency level different from the proficiency level of worker po in the past, and experiences a danger caused by a behavior of that other worker po.

The third proficiency level setting method will be described. Proficiency level setter 13 selects, as the proficiency level of other worker po, the setting level of a proficiency level with less collaborative work experience for work trainee pt from among the setting levels of stepped proficiency levels. When the setting level of a proficiency level with much collaborative work experience is A (see FIG. 5), for example, proficiency level setter 13 sets the proficiency level of other worker po to B, C, D, or E. When a plurality of other workers po are present, proficiency level setter 13 may assign proficiency levels B, C, D, and E to the plurality of other workers po. Proficiency level setter 13 may select B or D that is the setting level of a proficiency level with least collaborative work experience. Thus, work trainee pt works with other worker po having the setting level of a proficiency level with less collaborative work experience, and experiences a danger caused by a behavior of that other worker po.

One of these three proficiency level setting methods may be selected by an operation input performed using UI device 30 or selected randomly by simulation device 10. By thus setting the proficiency level of other worker po, work trainee pt can have, in a work simulation, an experience that work trainee pt has never experienced. The proficiency level of other worker po set by proficiency level setter 13 is output to behavior generator 19.

Behavior generator 19 is a processing circuit that generates a behavior of other worker po in the simulation in accordance with the proficiency level of other worker po.

For example, behavior generator 19 generates an unsafe behavior on a work site, and causes other worker po to perform the unsafe behavior. In this case, unsafe behavior extractor 15 extracts an unsafe behavior of work trainee pt in the past based on work achievement information i obtained by information obtainer 11. The unsafe behavior in the past is extracted from work achievement information i of work trainee pt. The unsafe behavior in the past is not limited to be extracted from work achievement information i of work trainee pt, but may be extracted from unsafe behaviors included in work achievement information i of other worker p2, p3, or p4. An unsafe behavior may be set by database server 20 or simulation device 10 in advance as a training menu in a work simulation.

Behavior generator 19 generates an unsafe behavior of other worker po on a work site based on the unsafe behavior in the past extracted by unsafe behavior extractor 15. The unsafe behavior generated by behavior generator 19 is output to UI device 30 as video information and sound information related to an unsafe behavior. UI device 30 provides work trainee pt with the video information and the sound information related to an unsafe behavior that have been output from behavior generator 19.

Behavior generator 19 may generate a behavior in work with high accident probability and cause other worker po to perform the behavior. In this case, dangerous work setter 17 sets dangerous work with high accident probability based on unsafe behaviors in the past. For example, dangerous work setter 17 extracts, from the work details illustrated in FIG. 6, dangerous work with high probability at which an accident occurs when one of the unsafe behaviors is performed.

Behavior generator 19 generates a behavior of other worker po on a work site based on the dangerous work set by dangerous work setter 17. The behavior in the dangerous work, which has been generated by behavior generator 19, is output to UI device 30 as video information and sound information related to a behavior in dangerous work. UI device 30 presents the video information related to dangerous work with high accident probability to actual (real) work trainee pt, and also provides actual (real) work trainee pt with the sound information.

Work simulation system 1 according to the present embodiment includes: information obtainer 11 that obtains work achievement information i of work trainee pt who participates in a work simulation; proficiency level setter 13 that sets the proficiency level of other worker po in the vicinity of work trainee pt on a work site based on work achievement information i; and behavior generator 19 that generates a behavior of other worker po on the work site in accordance with the proficiency level of other worker po. By thus generating a behavior of other worker po in accordance with the proficiency level of other worker po, it is possible to conduct work training in which the behavior of other worker po is reflected.

### [Work Simulation Method]

A work simulation method according to the embodiment will be described with reference to FIG. 8.

FIG. 8 is a flowchart illustrating the work simulation method according to the embodiment.

Simulation device 10 obtains work achievement information i of work trainee pt (step S10). Work achievement information i includes identification information of a worker, a work history, and information regarding the proficiency level of work trainee pt. Simulation device 10 may obtain not only work achievement information i of work trainee pt, but at the same time, also work achievement information i of each of other workers p2, p3, and p4 different from work trainee pt.

Subsequently, simulation device 10 sets the proficiency level of other worker po in the vicinity of work trainee pt who participates in a work simulation, based on the obtained work achievement information i (step S20).

Simulation device 10 sets, as the proficiency level of other worker po, a proficiency level different from the proficiency level of work trainee pt. Simulation device 10 may also set, as the proficiency level of other worker po, a proficiency level different from the proficiency level of other worker po with whom work trainee pt has worked in collaboration in the past. Simulation device 10 may set, as the proficiency level of other worker po, the setting level of a proficiency level with less collaborative work experience for work trainee pt from among the setting levels of stepped proficiency levels.

Subsequently, simulation device 10 generates a behavior of other worker po on a work site in accordance with the proficiency level of other worker po (step S30).

For example, simulation device 10 generates an unsafe behavior on a work site and causes other worker po to perform the unsafe behavior. More specifically, simulation device 10 extracts an unsafe behavior of a worker in the past based on work achievement information i, and sets dangerous work with high accident probability based on the unsafe behavior in the past. Simulation device 10 then generates a behavior of other worker po based on the dangerous work with high accident probability.

Simulation device 10 outputs the behavior with high accident probability of other worker po to UI device 30 as video information and sound information related to a behavior in dangerous work (step S40). UI device 30 provides work trainee pt with video information and sound information related to a behavior in dangerous work with high accident probability (step S50). By performing these steps S10 to S50, it is possible to conduct work training in which the behavior of other worker po is reflected.

### Variations of the Embodiment

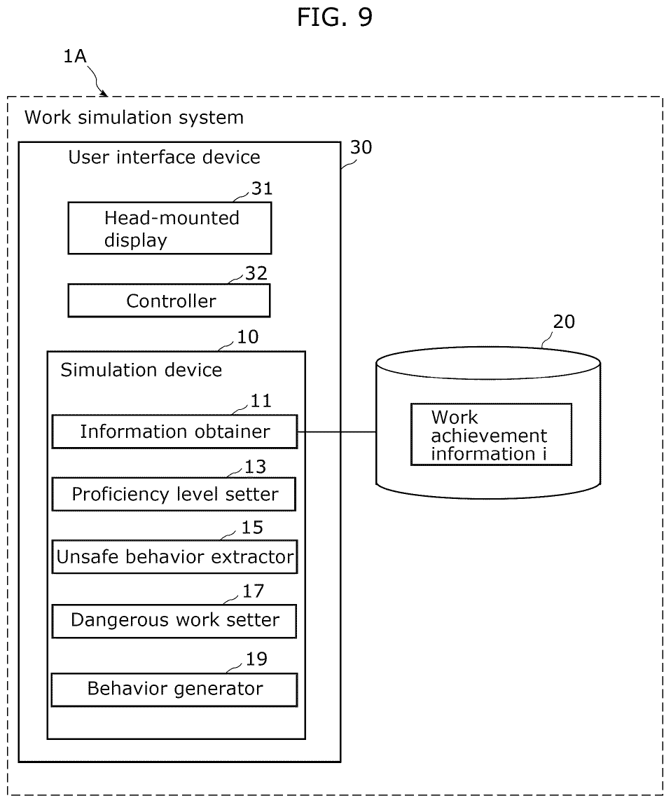

FIG. 9 is a diagram illustrating the configuration of work simulation system 1A according to Variation 1 of the embodiment. Work simulation system 1A illustrated in FIG. 9 includes simulation device 10, database server 20, and UI device 30. In work simulation system 1A according to Variation 1, simulation device 10 is provided inside UI device 30. Functions of simulation device 10 in this case are achieved by a microprocessor in HMD 31. Work simulation system 1A according to Variation 1 produces the same advantageous effects as work simulation system 1 according to the embodiment.

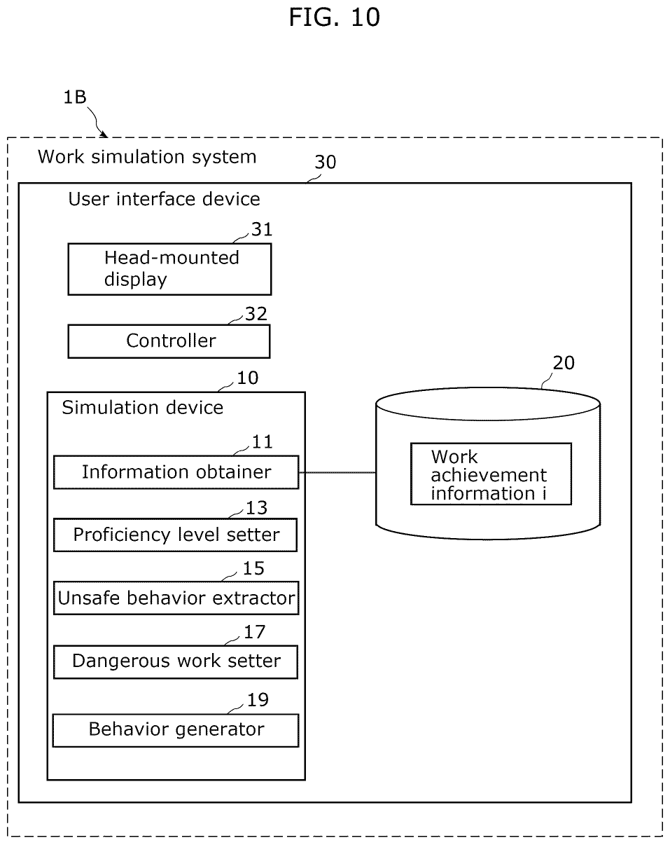

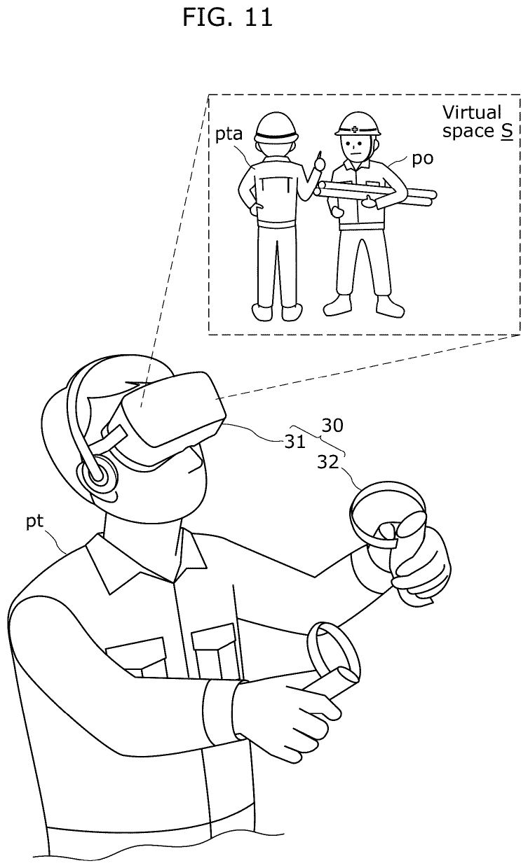

FIG. 10 is a diagram illustrating the configuration of work simulation system 1B according to Variation 2 of the embodiment.

Work simulation system 1B illustrated in FIG. 10 includes simulation device 10, database server 20, and UI device 30. In work simulation system 1B according to Variation 2, simulation device 10 and database server 20 are provided inside UI device 30. Functions of database server 20 in this case are achieved by memory in HMD 31. Work simulation system 1B according to Variation 2 produces the same advantageous effects as work simulation system 1 according to the embodiment.

FIG. 11 is a diagram illustrating another example of user interface device 30.

FIG. 11 illustrates avatar pta of work trainee pt in addition to other worker po in virtual space S. When work trainee pt receives training using UI device 30, for example, work trainee pt may experience dangerous work through avatar pta.

### Other Embodiments

Although the aspects of the work simulation system and so on have been described according to the embodiment, the aspects of the work simulation system and so on are not limited to the embodiment. Modifications may be made to the embodiment which may be conceived by those skilled in the art, and elements of the embodiment may be arbitrarily combined.

The aforementioned embodiment has illustrated an example in which work achievement information i is actual (real) work achievement information, but the present disclosure is not limited to this example. For example, work achievement information i of work trainee pt may include training achievement of work trainee pt in virtual space S in addition to the actual work achievement information of work trainee pt.

For example, a process executed by a specific element may be executed by a different element instead of the specific element in the embodiment. An order of processes may be changed or the processes may be executed in parallel. Ordinal numbers such as “first” and “second” used in the description may be changed, removed, or newly provided where necessary. These ordinal numbers do not necessarily correspond to an order that has a meaning and may be used for differentiating elements.

The work simulation method may be executed by any system or device. In other words, the work simulation method may be executed by, for instance, the work simulation system described above, or may be executed by other system or device.

For example, part or all of the work simulation method may be executed by a computer including, for instance, a processor, memory, and an input/output circuit. In such a case, the work simulation method may be executed by a computer executing a program for causing the computer to execute the work simulation method.

The program may be recorded on a non-transitory computer-readable recording medium such as a CD-ROM.

Moreover, constituent elements of, for instance, the work simulation system may be configured by dedicated hardware or general hardware that executes the aforementioned program, or a combination of these hardware. The general hardware may be configured by memory in which the program is recorded and a general processor that reads out the program from the memory to execute the program. The memory may be semiconductor memory, a hard disk, or the like, and the general processor may be a CPU or the like.

The dedicated hardware may be configured by, for instance, memory and a dedicated processor. For example, the dedicated processor may reference the memory to execute the aforementioned work simulation method described above.

Each constituent element of the work simulation system may be an electrical circuit. These electrical circuits may be included in a single electrical circuit as a whole or may be separate circuits.

Moreover, these electrical circuits may correspond to dedicated hardware or general hardware that executes the aforementioned program or the like.

### INDUSTRIAL APPLICABILITY

The present disclosure is applicable to, for instance, a system that performs a work simulation simulating work on a work site in a virtual space.

1. A work simulation system that performs a work simulation simulating work on a work site in a virtual space, the work simulation system comprising:
an information obtainer that obtains work achievement information of a work trainee who participates in the work simulation;
a proficiency level setter that sets a proficiency level of an other worker in a vicinity of the work trainee on the work site based on the work achievement information; and
a behavior generator that generates a behavior of the other worker on the work site in accordance with the proficiency level of the other worker.

2. The work simulation system according to claim 1, wherein the behavior generator generates an unsafe behavior on the work site and causes the other worker to perform the unsafe behavior.

3. The work simulation system according to claim 1, wherein
the behavior generator generates a behavior in work with high accident probability and causes the other worker to perform the behavior.

4. The work simulation system according to claim 1, wherein
the proficiency level setter sets, as the proficiency level of the other worker, a proficiency level different from a proficiency level of the work trainee.

5. The work simulation system according to claim 1, wherein
the proficiency level setter sets, as the proficiency level of the other worker, a proficiency level different from a proficiency level of an other worker with whom the work trainee has worked in collaboration in a past.

6. The work simulation system according to claim 1, wherein
the proficiency level setter selects, as the proficiency level of the other worker, a setting level of a proficiency level with less collaborative work experience for the work trainee from among setting levels of stepped proficiency levels.

7. The work simulation system according to claim 2, further comprising:
an unsafe behavior extractor that extracts an unsafe behavior of the work trainee in a past based on the work achievement information, wherein
the behavior generator generates an unsafe behavior on the work site based on the unsafe behavior in the past extracted by the unsafe behavior extractor.

8. The work simulation system according to claim 2, further comprising:
an unsafe behavior extractor that extracts an unsafe behavior of the work trainee in a past based on the work achievement information; and
a dangerous work setter that sets dangerous work with high accident probability based on the unsafe behavior in the past, wherein
the behavior generator generates a behavior of the other worker based on the dangerous work with high accident probability set by the dangerous work setter.

9. The work simulation system according to claim 2, further comprising:
an unsafe behavior extractor that extracts an unsafe behavior of the work trainee in a past based on the work achievement information;
a dangerous work setter that sets dangerous work with high accident probability based on the unsafe behavior in the past; and
a user interface device that presents the dangerous work with high accident probability.

10. A work simulation system that performs a work simulation simulating work on a work site in a virtual space, the work simulation system comprising:
an information obtainer that obtains work achievement information of a work trainee who participates in the work simulation; and
a behavior generator that generates a behavior of an other worker in a vicinity of the work trainee on the work site based on the work achievement information.

11. A work simulation method of performing a work simulation simulating work on a work site in a virtual space, the work simulation method comprising:
obtaining work achievement information of a work trainee who participates in the work simulation;
setting a proficiency level of an other worker in a vicinity of the work trainee on the work site based on the work achievement information; and
generating a behavior of the other worker on the work site in accordance with the proficiency level of the other worker.

12. A non-transitory computer-readable recording medium for use in a computer, the recording medium having recorded thereon a computer program for causing the computer to execute the work simulation method according to claim 11.
